(19) United States
(12) Patent Application Publication
(10) Pub. No.: US 2024/0363524 A1
(43) Pub. Date: Oct. 31, 2024

(54) GOUGED INTERCONNECT LINE

(71) Applicant: INTERNATIONAL BUSINESS MACHINES CORPORATION, ARMONK, NY (US)

(72) Inventors: Nicholas Anthony Lanzillo, Wynantskill, NY (US); Brent A. Anderson, Jericho, VT (US); Lawrence A. Clevenger, Saratoga Springs, NY (US); Albert M. Chu, Nashua, NH (US); Reinaldo Vega, Mahopac, NY (US); Ruilong Xie, Niskayuna, NY (US)

(21) Appl. No.: 18/306,267

(22) Filed: Apr. 25, 2023

(51) Int. Cl. H01L 23/522; H01L 21/768

(52) U.S. Cl. CPC H01L 23/5226; H01L 21/76816; H01L 21/76831; H01L 21/7684

(57) ABSTRACT

Embodiments of present invention provide an interconnect structure. The structure includes a metal line embedded in a dielectric layer; a first via intersecting with the metal line; and a second via intersecting with the metal line, the second via being horizontally separated from the first via by a length that is less than a blech length of the metal line, where the first and the second via extend vertically at least from a top surface of the metal line to a bottom surface of the metal line and have a width that is equal to or large than a width of the metal line. One or more method of forming the same are also provided.

### BACKGROUND

The present application relates to manufacturing of semiconductor integrated circuits. More particularly, it relates to metal lines in interconnect structures and method of making the same.

Electromigration is the movement of atoms based on the flow of current through a material. If the current density is high enough, the heat dissipated within the material will repeatedly break atoms from the structure and cause them to move. This will create both vacancies and deposits of the material. The vacancies may grow and eventually break the circuit connections resulting in an open-circuit. On the other hand, the deposits of the material may grow and eventually close circuit connections resulting in short-circuit.

Electromigration is a particular design concern in back-end-of-line (BEOL) structures when making integrated circuits. In general, a BEOL structure includes various interconnect structures that in-turn include various metal lines of different widths and/or lengths. In a highly scaled technology node, electromigration places severe limit on how much current a metal line may be able to carry without causing open and/or short circuits. In order to be able to carry more current, people may have to increase the size of the metal line and/or limit the type of material that may be used in making the metal lines, both of which are not ideal or desirable in terms of cost and the highly scaled nature in today's competitive semiconductor IC industry.

### SUMMARY

Embodiments of present invention provide an interconnect structure. The structure includes a metal line embedded in a dielectric layer; and a via intersecting with the metal line, where the via extends vertically at least from a top surface of the metal line to a bottom surface of the metal line and has a width that is equal to or larger than a width of the metal line.

In one embodiment, the via is a first via, and the structure further includes a second via intersecting with the metal line, where the second via is separated from the first via along the metal line by a length that is less than a blech length of the metal line.

In another embodiment, the metal line is a first metal line, and the structure further includes a second metal line above the first metal line, where the first via connects the first metal line with the second metal line.

In yet another embodiment, the structure further includes a third metal line above the first metal line, wherein the third metal line is above the second via, and electrically isolated from the second via by the dielectric layer.

According to one embodiment, the second and the third metal line are formed parallel to each other and placed in an orientation that is orthogonal to the first metal line.

In one embodiment, the via includes a conductive liner at a first and a second sidewall of the via and where the metal line is in direct contact with the conductive liner of the via at the first and the second sidewall.

In another embodiment, the conductive liner of the via is a conformal conductive liner, and a portion of the conductive liner that covers a bottom of the via is below the bottom surface of the metal line.

In yet another embodiment, the conductive liner of the via is a first conductive liner, where the metal line includes a second conductive line at sidewalls thereof and at the bottom surface of the metal line, where the second conductive liner is materially different from the first conductive liner.

According to one embodiment, the metal line is a first metal line, and the via further extends below the bottom surface of the first metal line to reach a second metal line beneath the first metal line. In one embodiment, the second metal line is placed in an orientation that is orthogonal to the first metal line. In another embodiment, the via includes a conductive liner that covers a top surface and surrounds sidewalls of the via.

Embodiments of present invention also provide a method of forming an interconnect structure. The method includes forming a metal line and a via in contact with the metal line, where the via has a height and a width that are sufficiently tall and wide to completely truncate the metal line.

In one embodiment, forming the metal line and the via includes forming the metal line in a dielectric layer; creating a gouge through the metal line, the gouge being sufficiently deep and wide to completely truncate the metal line; forming a conductive liner lining the gouge; and depositing a conductive material in the gouge thereby forming the via.

In another embodiment, forming the metal line and the via includes forming a first conductive layer on top of a first dielectric layer; patterning the first conductive layer to form at least the via; forming a second conductive layer surrounding a top portion of the via; and patterning the second conductive layer to form the metal line.

In a further embodiment, the method further includes depositing a second dielectric layer surrounding the via, the second dielectric layer leaving the top portion of the via exposed; and forming the second conductive layer on top of the second dielectric layer, surrounding the top portion of the via. In a yet further embodiment, the method includes planarizing the second conductive layer to expose a top surface of the via.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B are demonstrative illustrations of cross-sectional views of an interconnect structure according to one embodiment of present invention;

FIG. 2 is a demonstrative illustration of cross-sectional view of an interconnect structure according to another embodiment of present invention;

FIG. 3 is a demonstrative illustration of cross-sectional view of an interconnect structure according to yet another embodiment of present invention;

FIGS. 4A and 4B are demonstrative illustrations of cross-sectional views of an interconnect structure according to a further embodiment of present invention;

FIGS. 5A, 5B, 5C, 5D, 5E, and 5F are demonstrative illustrations of cross-sectional views of an interconnect structure in a process of manufacturing thereof according to one embodiment of present invention;

FIGS. 6A, 6B, 6C, 6D, 6E, and 6F are demonstrative illustrations of cross-sectional views of an interconnect structure in a process of manufacturing thereof according to another embodiment of present invention;

FIGS. 7A, 7B, 7C, 7D, 7E, and 7F are demonstrative illustrations of cross-sectional views of an interconnect structure in a process of manufacturing thereof according to yet another embodiment of present invention;

FIG. 8 is a demonstrative illustration of a flow-chart of a method of manufacturing an interconnect structure according to one embodiment of present invention; and

FIG. 9 is a demonstrative illustration of a flow-chart of a method of manufacturing an interconnect structure according to another embodiment of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, the same or similar reference numbers are used throughout the drawings to denote the same or similar features, elements, or structures, and thus, a detailed explanation of the same or similar features, elements, or structures may not be repeated for each of the drawings for economy of description.

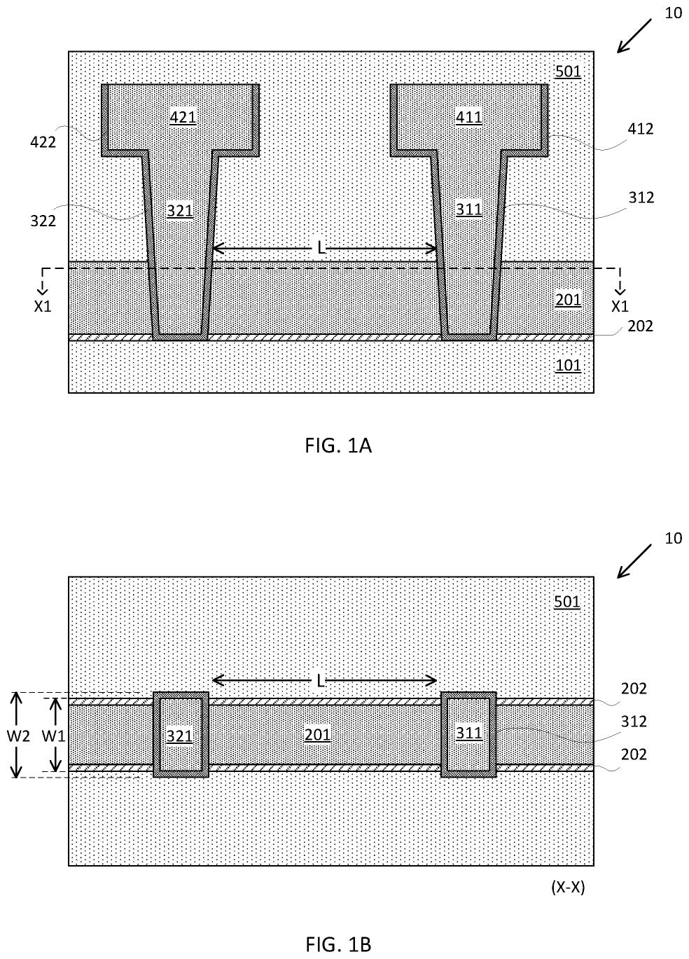

FIGS. 1A and 1B are demonstrative illustrations of cross-sectional views of an interconnect structure according to one embodiment of present invention. More specifically, FIG. 1A is a vertical cross-sectional view and FIG. 1B is a horizontal cross-sectional view, taken at a location labelled X1-X1 as indicated in FIG. 1A, of the interconnect structure.

More particularly, FIGS. 1A and 1B illustrate an interconnect structure 10 that may include, or be formed on top of, a supporting structure such as, for example, a portion of a substrate or a dielectric layer 101. One or more metal lines, such as a first metal line 201, may be formed on top of the dielectric layer 101. One or more vias, such as a first via 311 and/or a second via 321, may be formed in contact with and, more particularly, intersecting with the metal line 201. In addition, the first and the second via 311 and 321 may contact, or may be connected to, one or more additional metal lines such as a second metal line 411 and a third metal line 421 that are formed above the first metal line 201. The first metal line 201, the first and the second via 311 and 321, and the second and the third metal line 411 and 421 may be embedded in a dielectric layer 501.

In one embodiment, the first via 311 and/or the second via 321 may extend vertically at least from a top surface of the first metal line 201 to a bottom surface of the first metal line 201. The first via 311 and/or the second via 321 may have a width that is equal to or larger (or wider) than a width of the first metal line 201 such that the first and the second via 311 and 321 may fully or completely truncate the first metal line 201. For example, as is illustrated in FIG. 1B, the first metal line 201 may have a width W1 (referred to herein as a first width) and the first and the second via 311 and 321 may have a width W2 (referred to herein as a second width) and the second width W2 is equal to or larger than the first width W1.

In one embodiment, the first via 311 and the second via 321 may be separated horizontally, and along the first metal line 201, by a length L that is less than a blech length of the first metal line 201. The first and the second via 311 and 321, since being placed less than a blech length apart, prevent the first metal line 201 from failure that may potentially be caused by electromigration. A blech length is a length or distance below which an electrical wire, such as the first metal line 201, will not fail by electromigration. For example, when the first metal line 201 is made of copper, the first and the second via 311 and 321 may be separated by a length less than about, for example, 100 nm which also depends on the size of pitch, width of the interconnect, as well as the interconnect material.

In another embodiment, the first via 311 and/or the second via 321 may include a conductive liner such as, for example, a conductive liner 312 and a conductive liner 322, respectively, at sidewalls and bottoms of the first and the second via 311 and 321 respectively. For example, as is illustrated in FIG. 1A, the conductive liner 312 may cover a left (first) sidewall and a right (second) sidewall of the first via 311 and the first metal line 201 may be in direct contact with the conductive liner 312 at the left and right sidewalls of the first via 311. The first metal line 201 may include a conductive liner 202 at sidewalls and a bottom of the first metal line 201. The first metal line 201 may be in direct contact with the conductive liner 312 of the first via 311 without going through the conductive liner 202 of the first metal line 201.

In one embodiment, the conductive liner 312 and 322 may be conformal conductive liners formed through for example a conformal deposition process; and may be formed in a material that is different from a material used for forming the conductive liner 202 that surrounds the first metal line 201. In another embodiment, the first via 311 may be formed to have a bottom surface that is below a bottom surface of the first metal line 201, resulting in a conductive liner 312, which covers the bottom of the first via 311, being at a level below the bottom surface of the first metal line 201.

In yet another embodiment, the second metal line 411 and the third metal line 421 may be placed or formed in an orientation that is orthogonal to the first metal line 201. For example, the first metal line 201 may be laid out or formed to run from left to right (parallel to the paper) while the second and the third metal line 411 and 421 may be laid out or formed to run into and/or out of the paper, in a direction that is perpendicular or orthogonal to the first metal line 201.

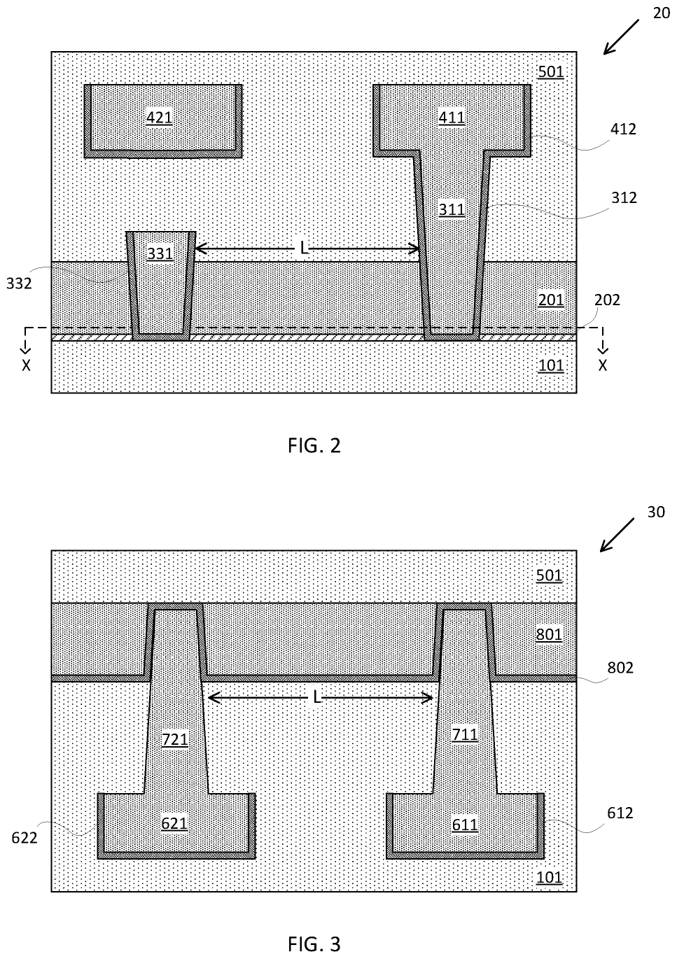

FIG. 2 is a demonstrative illustration of cross-sectional view of an interconnect structure according to one embodiment of present invention. More particularly, embodiments of present invention provide an interconnect structure 20 that includes, for example, a first via 311, a second via 331, and a first metal line 201 where the first and the second via 311 and 332 fully or completely truncate the first metal line 201 by being sufficiently deep or tall and sufficiently wide. The interconnect structure 20 is similar to the interconnect structure 10 except that, as is clear by comparing FIG. 2 with FIG. 1A, the second via 331 of the interconnect structure 20 may be electrically isolated from the third metal line 421 by a dielectric layer 501. In other words, the second via 331 is only electrically connected to the first metal line 201 and is not connected to any other metal lines at a top thereof, and for that matter at a bottom thereof as well. The first and the second via 311 and 331 are horizontally separated along the first metal line 201 by a length less that a blech length of the first metal line 201.

FIG. 3 is a demonstrative illustration of cross-sectional view of an interconnect structure according to one embodiment of present invention. More particularly, embodiments of present invention provide an interconnect structure 30 that includes at least a first metal line 801 sitting on top of a supporting structure such as, for example, a dielectric layer 101 and surrounded by a dielectric layer 501. One or more vias, such as a first via 711 and/or a second via 721, may be formed in contact with and, more particularly, intersecting with the metal line 801. In one embodiment, the first and the second via 711 and 721 may extend vertically and downwardly, from a top surface of the first metal line 801 through the first metal line 801, to reach one or more additional metal lines such as a second metal line 611 and a third metal line 621 that are underneath the first metal line 801. The first via 711 and/or the second via 721 may have a width that is equal to or larger than a width of the first metal line 801 such that the first and the second via 711 and 721 may fully or completely truncate the first metal line 801. The second and the third metal line 611 and 621 may be placed or formed in an orientation that is orthogonal to the first metal line 801.

The first metal line 801 and an upper portion of the first and the second via 711 and 721 may be embedded in the dielectric layer 501. A lower portion of the first and the second via 711 and 721, together with the second and the third metal line 611 and 621, may be embedded in the dielectric layer 101. In one embodiment, the first via 711 and the second via 721 may be separated by a length L that is less than a blech length of the first metal line 801.

In one embodiment, the first via 711 and the second via 721 may include a conductive liner 802 that covers top surfaces and sidewalls of the upper portions of the first and the second via 711 and 721. In other words, the conductive liner 802 may be shared by the first and the second via 711 and 721. Additionally, the first metal line 801 may share the conductive liner 802 with the first and the second via 711 and 721 at a bottom thereof. The first metal line 801 may contact the conductive liner 802 directly at the sidewalls of the first and the second via 711 and 721 without going through any existing conductive liner of the first metal line 801. In one embodiment, the conductive liner 802 may be a conformal conductive liner.

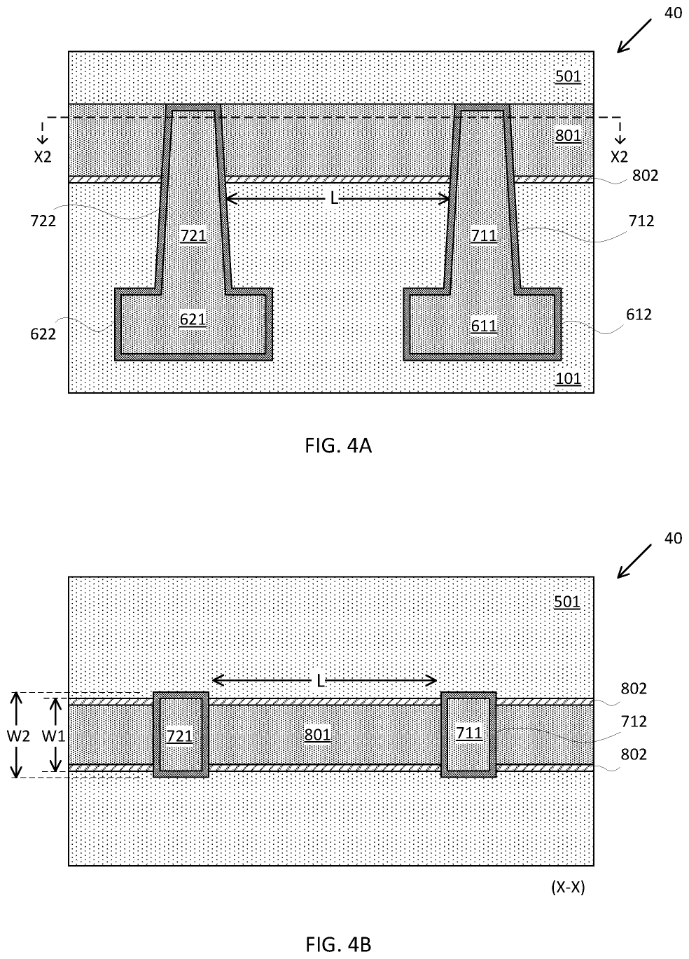

FIGS. 4A and 4B are demonstrative illustrations of cross-sectional views of an interconnect structure according to one embodiment of present invention. More specifically, FIG. 4A is a vertical cross-sectional view and FIG. 4B is a horizontal cross-sectional view, taken at a location labelled X2-X2 as indicated in FIG. 4A, of an interconnect structure 40.

More particularly, FIGS. 4A and 4B illustrate an interconnect structure 40 that includes at least a first metal line 801 on top of a supporting structure such as, for example, a dielectric layer 101. One or more vias, such as a first via 711 and/or a second via 721, may be formed to be in contact with and, more particularly, intersect with the first metal line 801. The first and second vias 711 and 721 may extend vertically at least from a top surface of the first metal line 801 downwardly to contact one or more additional metal lines such as a second metal line 611 and a third metal line 621 underneath the first metal line 801. The second and the third metal line 611 and 621 may be placed or formed to be orthogonal to the first metal line 801. The first metal line 801, the first and the second via 711 and 721, and the second and the third metal line 611 and 621 may be embedded in one or more dielectric layers such as dielectric layer 101 and 501.

In one embodiment, the first via 711 and/or the second via 721 may have a width that is equal to or larger (or wider) than a width of the first metal line 801 such that the first and the second via 711 and 721 may fully or completely truncate the first metal line 801. For example, as is illustrated in FIG. 4B, the first metal line 801 may have a width W1, referred to herein as a first width, and the first and the second via 711 and 721 may have a width W2, referred to herein as a second width, and the second width W2 is equal to or larger than the first width W1.

In one embodiment, the first via 711 and the second via 721 may be separated by a length L that is less than a blech length of the first metal line 801. The first and the second via 711 and 721, since being placed less than a blech length apart, prevent the first metal line 801 from failure that may potentially be caused by electromigration.

In another embodiment, the first via 711 and the second via 721 may each include a conductive liner such as a conductive liner 712 and a conductive liner 722, respectively, at sidewalls and bottoms of the first and the second via 711 and 721. The interconnect structure 40 may be similar to the interconnect structure 30, except that the first and the second via 711 and 721 as well as the bottom of the first metal line 801 do not share a common conductive liner such as the common conductive liner 802 illustrated in FIG. 3. However, the first metal line 801 may be in direct contact with the conductive liner 712 of the first via 711 at a left (first) and a right (second) sidewall thereof, and in direct contact with the conductive liner 722 of the second via 721 at a left (first) and a right (second) sidewall thereof as well. The conductive liner 802 surrounding the first metal line 801 in the embodiment illustrated in FIG. 4A may be made from a same or different material from that of the conductive liners 712 and 722. In one embodiment, the conductive liners 712 and 722 may be conformal conductive liners and may be formed through a conformal deposition process.

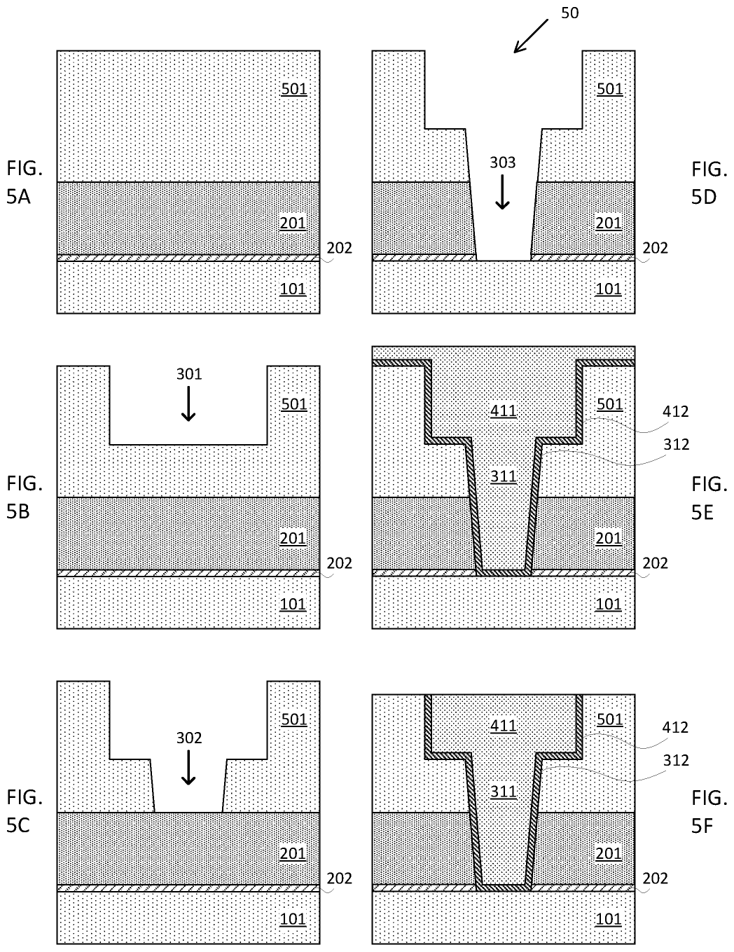

FIGS. 5A, 5B, 5C, 5D, 5E, and 5F are demonstrative illustrations of cross-sectional views of an interconnect structure in a process of manufacturing thereof according to one embodiment of present invention. More particularly, as is illustrated in FIG. 5A, the embodiment includes providing a supporting structure such as a first dielectric layer 101; forming a first metal line 201, with a conductive liner 202 at a bottom and sidewalls thereof, on top of the first dielectric layer 101; and covering the first metal line 201 with a second dielectric layer 501. Next, the embodiment provides creating a trench opening 301 in the second dielectric layer 501, as is illustrated in FIG. 5B, for forming a second metal line and creating a via opening 302 in an area in the trench opening 301 in the second dielectric layer 501 as is illustrated in FIG. 5C. The creation of the trench opening 301 and the via opening 302 may be made by a dual damascene process or by two separate single damascene processes that involve lithographic patterning and etching. Next, the embodiment provides gouging or etching through the first metal line 201 completely to create a gouge 303 that truncates the first metal line 201 and the conductive liner 202 that surrounds the first metal line 201, as is illustrated in FIG. 5D. For example, the gouge 303 may be sufficiently deep and in the meantime have a width that is equal to or larger than a width of the first metal line 201. After truncating the first metal line 201, the embodiment provides forming a conductive liner 312 lining the gouge 303, the via opening 302, and the trench opening 301 as is illustrated in FIG. 5E. The conductive liner 312 may be a conformal conductive liner such as, for example, a tantalum-nitride (TaN) or a titanium-nitride (TiN) and may be formed through a conformal deposition process. On top of the conductive liner 312, a conductive material, such as cupper (Cu) or aluminum (Al), may be deposited to form a via 311 and a second metal line 411 on top of the via 311. The second metal line 411 may be formed in an orientation that is orthogonal to the first metal line 201.

Next, the embodiment provides applying a chemical-mechanic-polishing (CMP) process to planarize a top surface of the second metal line 411 as well as the second dielectric layer 501 as is illustrated in FIG. 5F. Additional vias, similar to the via 311 that truncate the first metal line 201 may be formed that are separated from the via 311 by a distance or length that is less than a blech length of the first metal line 201. By forming two or more vias that are separated less than the blech length of the first metal line 201, embodiments of present invention provide an interconnect structure 50, and a method of forming the same, that may be able to avoid and/or eliminate electromigration related damages.

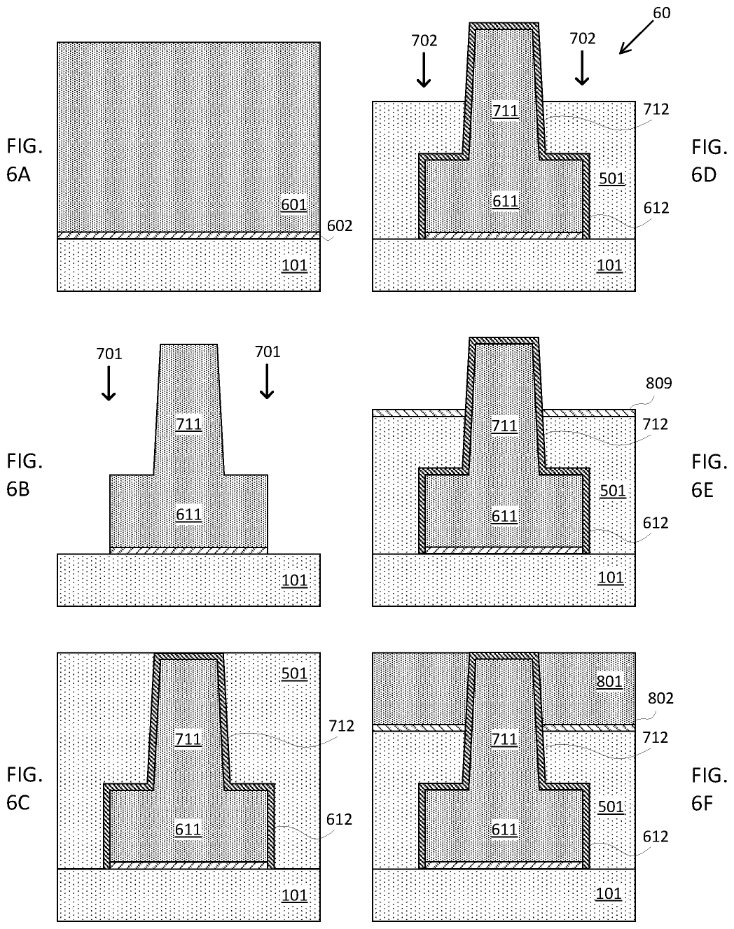

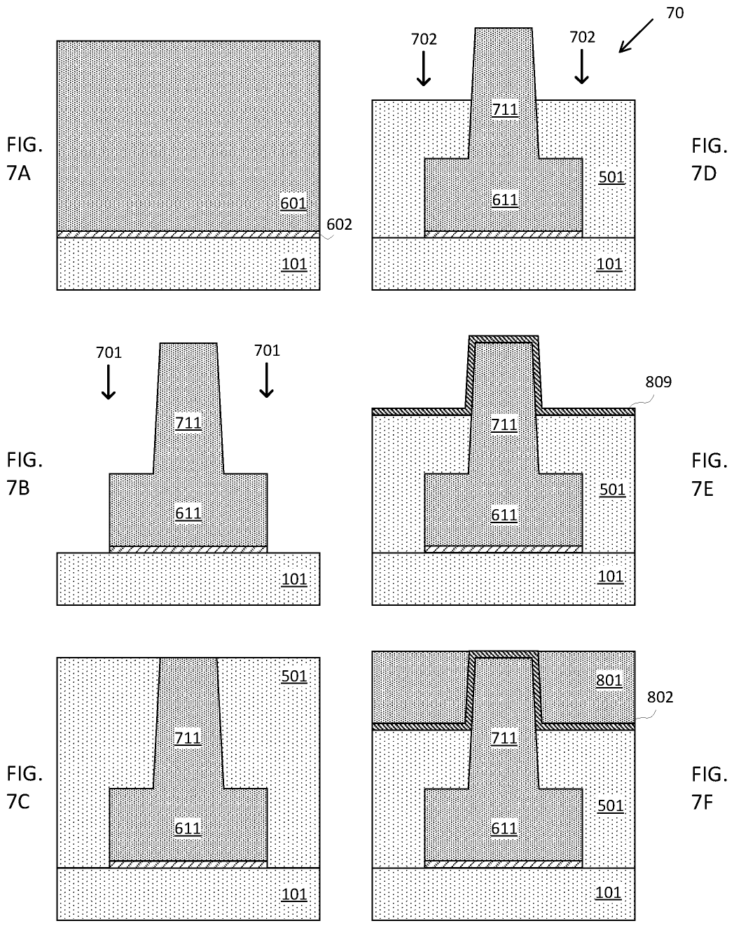

FIGS. 6A-6F are demonstrative illustrations of cross-sectional views of an interconnect structure in a process of manufacturing thereof according to another embodiment of present invention. More particularly, as is illustrated in FIG. 6A, the embodiment includes providing a supporting structure such as a first dielectric layer 101; depositing a conductive liner layer 602 on top of the first dielectric layer 101; and forming a second metal layer 601 on top of the conductive liner layer 602. Next, the embodiment provides patterning the second metal layer 601 and the conductive liner layer 602 underneath thereof, through an etching process 701, to form a second metal line 611 and a via 711 on top of the second metal line 611 as is illustrated in FIG. 6B. The embodiment further provides forming a conductive liner 612 surrounding the via 711 and the second metal line 611 as is illustrated in FIG. 6C. The conductive liner 612 may be formed through a selective deposition process where the conductive liner 612 may be deposited only on top of conductive material such as that of the via 711 and the second metal line 611. The embodiment then provide depositing a second dielectric layer 501 on top of the conductive liner 612 and the first dielectric layer 101 to cover the via 711 and the second metal line 611. A CMP process may be applied to planarize a top surface of the second dielectric layer 501 until the conductive liner 612 at the top of the via 711 is exposed. Next, as is illustrated in FIG. 6D, the second dielectric layer 501 may be recessed, through a selective etching process, to expose a top portion of the via 711. A conductive liner layer 809 may optionally be formed on top of the recessed second dielectric layer 501 through a selective metal deposition process, as is illustrated in FIG. 6E, or may be formed to cover both the top of the recessed second dielectric layer 501 and the top portion of the via 711 in a blanket deposition process. Subsequently, a blanket metal layer may then be deposited on top of the conductive liner layer 809 and the blanket metal layer and the conductive liner layer 809 may subsequently be patterned to form a first metal line 801 and a conductive liner 802 at a bottom of the first metal line 801 as is illustrated in FIG. 6F. Following the patterning of the first metal line 801, additional dielectric material may be deposited to surround the first metal line 801.

Additional vias, similar to the via 711 that truncate the first metal line 801, may be formed similarly in a same step (or in separate steps as well) as when forming the via 711. These additional vias may be separated from the via 711 by a distance or length that is less than a blech length of the first metal line 801. By forming two or more vias that are separated less than the blech length of the first metal line 801, embodiments of present invention provide an interconnect structure 60, and a method of forming the same, that may be able to avoid and/or eliminate electromigration related damages.

FIGS. 7A-7F are demonstrative illustrations of cross-sectional views of an interconnect structure in a process of manufacturing thereof according to yet another embodiment of present invention. More particularly, as is illustrated in FIG. 7A, the embodiment includes providing a supporting structure such as a first dielectric layer 101; depositing a conductive liner layer 602 on top of the first dielectric layer 101; and forming a second metal layer 601 on top of the conductive liner layer 602. Next, the embodiment provides patterning the second metal layer 601 and the conductive liner layer 602 underneath thereof, through an etching process 701, to form a second metal line 611 and a via 711 on top of the second metal line 611 as is illustrated in FIG. 7B. The embodiment further provides depositing a second dielectric layer 501 on top of the first dielectric layer 101 and covering the via 711 and the second metal line 611 as is illustrated in FIG. 7C. A CMP process may be applied to planarize a top surface of the second dielectric layer 501. Next, as is illustrated in FIG. 7D, the second dielectric layer 501 may be recessed, through a selective etching process, to expose a top portion of the via 711. A conductive liner layer 809 such as a titanium-nitride (TiN) may then be formed on top of the recessed second dielectric layer 501 and on the top portion of the via 711, as is illustrated in FIG. 7E. Subsequently, a blanket metal layer may then be deposited on top of the conductive liner layer 809 and the blanket metal layer and the conductive liner layer 809 may be patterned to form a first metal line 801 and a conductive liner 802 at a bottom of the first metal line 801 as is illustrated in FIG. 7F. Following the patterning of the first metal line 801, additional dielectric material may be deposited to surround the first metal line 801.

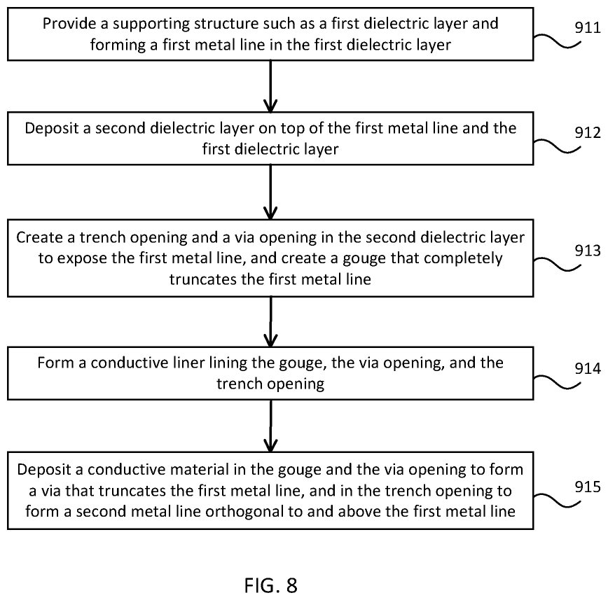

FIG. 8 is a demonstrative illustration of a flow-chart of a method of manufacturing an interconnect structure according to one embodiment of present invention. More specifically, the embodiment includes (911) providing a supporting structure such as a first dielectric layer and forming a first metal line in the first dielectric layer, the first metal line may include a conductive liner at a bottom and sidewalls thereof; (912) depositing a second dielectric layer on top of the first metal line and the first dielectric layer; (913) creating a trench opening and a via opening in the second dielectric layer to expose the first metal line and creating a gouge in the first metal line through the via opening, the gouge may be made sufficiently deep and wide such that it completely truncates the first metal line; (914) forming a conductive liner, which may be a conformal liner, lining the trench opening, the via opening, and the gouge; and (915) depositing a conductive material in the gouge and the via opening to form a via, resulting in a via that truncates the first metal line, and depositing the conductive material in the trench opening to form a second metal line directly in contact with the via and orthogonally above the first metal line. The second metal line may be surrounded or embedded in the second dielectric layer.

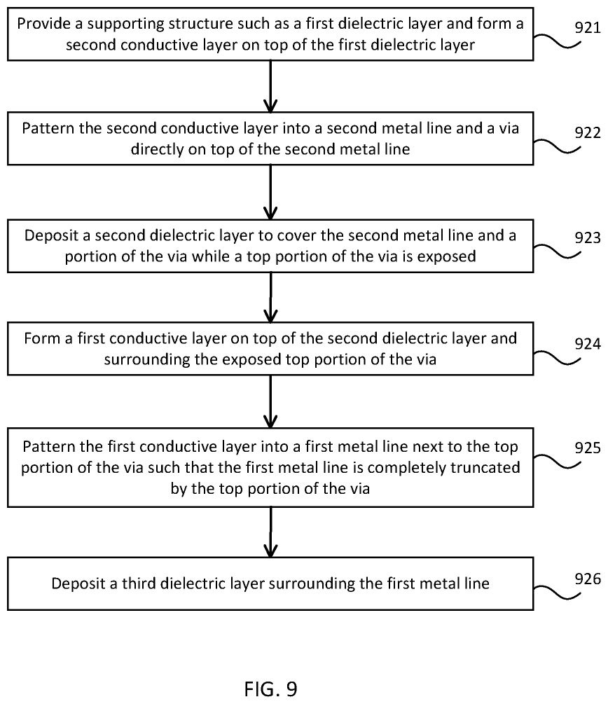

FIG. 9 is a demonstrative illustration of a flow-chart of a method of manufacturing an interconnect structure according to another embodiment of present invention. More specifically, the embodiment includes (921) providing a supporting structure such as a first dielectric layer and forming a second conductive layer on top of the first dielectric layer; (922) patterning the second conductive layer to form a second metal line and a via directly on top of the second metal line; (923) depositing a second dielectric layer on top of the first dielectric layer and the second metal line while keeping a top portion of the via exposed; (924) forming a first conductive layer on top of the second dielectric layer and surround the top portion of the via; and (925) patterning the second conductive layer to form a first metal line with the first metal line being fully and/or completely truncated by the exposed top portion of the via; and (926) depositing a third dielectric layer to surround the first metal line.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. An interconnect structure comprising:
a metal line embedded in a dielectric layer; and
a via intersecting with the metal line, intersecting
wherein the via extends vertically at least from a top surface of the metal line to a bottom surface of the metal line and has a width that is equal to or larger than a width of the metal line.

2. The interconnect structure of claim 1, wherein the via is a first via, further comprising a second via intersecting with the metal line, wherein the second via is separated from the first via along the metal line by a length that is less than a blech length of the metal line.

3. The interconnect structure of claim 2, wherein the metal line is a first metal line, further comprising a second metal line above the first metal line, wherein the first via connects the first metal line with the second metal line.

4. The interconnect structure of claim 3, further comprising a third metal line above the first metal line, wherein the third metal line is above the second via, and electrically isolated from the second via by the dielectric layer.

5. The interconnect structure of claim 4, wherein the second and the third metal line are formed parallel to each other and placed in an orientation that is orthogonal to the first metal line.

6. The interconnect structure of claim 1, wherein the via includes a conductive liner at a first and a second sidewall of the via and wherein the metal line is in direct contact with the conductive liner of the via at the first and the second sidewall.

7. The interconnect structure of claim 6, wherein the conductive liner of the via is a conformal conductive liner, and a portion of the conductive liner that covers a bottom of the via is below the bottom surface of the metal line.

8. The interconnect structure of claim 6, wherein the conductive liner of the via is a first conductive liner, wherein the metal line includes a second conductive line at sidewalls thereof and at the bottom surface of the metal line, wherein the second conductive liner is materially different from the first conductive liner.

9. The interconnect structure of claim 1, wherein the metal line is a first metal line, and the via further extends below the bottom surface of the first metal line to reach a second metal line beneath the first metal line.

10. The interconnect structure of claim 9, wherein the second metal line is placed in an orientation that is orthogonal to the first metal line.

11. The interconnect structure of claim 9, wherein the via includes a conductive liner that covers a top surface of the via and surrounds sidewalls of the via.

12. An interconnect structure comprising:
a metal line embedded in a dielectric layer;
a first via intersecting with the metal line; and
a second via intersecting with the metal line, the second via being horizontally separated from the first via by a length that is less than a blech length of the metal line,
wherein the first and the second via extend vertically at least from a top surface of the metal line to a bottom surface of the metal line and have a width that is equal to or larger than a width of the metal line.

13. The interconnect structure of claim 12, wherein the metal line is a first metal line, wherein at least the first via is electrically connected to a second metal line, the second metal line being above or below the first metal line and placed in an orientation that is orthogonal to the first metal line.

14. The interconnect structure of claim 13, wherein the first via includes a first conductive liner at sidewalls thereof and the first metal line includes a second conductive liner, and wherein the first metal line is in direct contact with the first conductive liner of the first via without going through the second conductive liner.

15. The interconnect structure of claim 14, wherein the conductive liner of the first via is a conformal conductive liner.

16. A method of forming an interconnect structure, the method comprising:
forming a metal line and a via in contact with the metal line, wherein the via has a height and a width that are sufficiently tall and wide to completely truncate the metal line.

17. The method of claim 16, wherein forming the metal line and the via comprises:
forming the metal line in a dielectric layer;
creating a gouge through the metal line, the gouge being sufficiently deep and wide to completely truncate the metal line;
forming a conductive liner lining the gouge; and
depositing a conductive material in the gouge thereby forming the via.

18. The method of claim 16, wherein forming the metal line and the via comprises:
forming a first conductive layer on top of a first dielectric layer;
patterning the first conductive layer to form at least the via;
forming a second conductive layer surrounding a top portion of the via; and
patterning the second conductive layer to form the metal line.

19. The method of claim 18, further comprising:
depositing a second dielectric layer surrounding the via, the second dielectric layer leaving the top portion of the via exposed; and
forming the second conductive layer on top of the second dielectric layer, surrounding the top portion of the via.

20. The method of claim 19, further comprising planarizing the second conductive layer to expose a top surface of the via.
